(19) United States
(12) Patent Application Publication
(10) Pub. No.: US 2012/0326933 A1
(43) Pub. Date: Dec. 27, 2012

(54) APPARATUS FOR MEASURING THE STRENGTH OF AN ELECTROMAGNETIC FIELD

(75) Inventors: Frank Leferink, de Lutte (NL); Frits Buesink, Hengelo (NL); Ramiro Serra, Eindhoven (NL)

(73) Assignee: Thales Nederland B.V., Hengelo (NL)

(21) Appl. No.: 13/334,450

(22) Filed: Dec. 22, 2011

(30) Foreign Application Priority Data
Dec. 22, 2010 (EP) 10196642.2

(51) Int. Cl. G01R 29/08

(52) U.S. Cl. 343/703

(57) ABSTRACT

There is disclosed an apparatus for measuring the strength of an electromagnetic field. The apparatus comprises a plurality of antennas arranged such that the field is received from all directions, each antenna supplying an RF signal as output. The apparatus also comprises a plurality of transforming modules, each of said modules being fed with the RF signal supplied by one of the antennas, each of said modules transforming the impedance of the RF signal it receives as input, so as to supply another RF signal as output. The apparatus also comprises a plurality of converting modules, each of said modules being fed with the RF signal supplied by one of the transforming modules, each of said modules converting the RF signal it receives as input into a DC current it supplies as output, said DC current varying substantially as a logarithmic function of the said RF signal.

### TECHNICAL FIELD

The present invention relates to a sensor for measuring the strength of electromagnetic (EM) fields. For example, the invention is particularly applicable to measuring EM fields in a test environment or to measuring a transfer function for evaluating the EM shielding effectiveness.

### BACKGROUND OF THE INVENTION

EM fields have to be measured in all kind of applications. For example, in some places EM fields have to be measured to establish the fields which could be dangerous to people. A problem is that modern communication systems are using digital modulating schemes with large differences between the peak and the average level, the so-called crest factor.

On the one hand, this cannot be measured easily using conventional systems, which are limited in range and speed. Those based on diode detectors are limited in dynamic range, while those based on thermocouples are limited in speed. As a consequence, they are not able of reading peaks. It is worth noting that the use of a series of diode to increase the dynamic range is of limited use.

On the other hand, advanced front-end, such as a Vertical Cavity Emitting Lasers, which convert electric signal to modulate an optical signal through an optical fibre interface, or super-heterodyne receivers are very expensive. In addition, the super-heterodyne receiver also needs a Radio-Frequency (RF) feed, which is sensitive to measurement errors when measuring fields.

In an attempt to provide a broad frequency band and broad power range device to warn people of electric fields hazards, the patent U.S. Pat. No. 6,727,859 B1 describes the use of a power measurement circuit as those coupled with a Received Signal Strength Indicator (RSSI) in modern base stations and mobile phones. These integrated circuits, which are referenced to as RSSI circuits in the present application, are using a cascade of diodes and amplifiers such that a logarithmic response results. They are usually used to control the power amplifier output of a mobile phone. They are very fast and able to detect the peak of a digital modulated signal.

For many reasons, the use of the warning device based on a wideband RSSI circuit, such as described in U.S. Pat. No. 6,727,859 B1, such a device not featuring measurement of the field with high accuracy, as an EM field strength sensor does not make sense a priori.

A first reason is that a wideband RSSI circuit is not adapted for use in a field strength sensor, because it has a too high noise level for extreme low amplitude field strength, thus leading to a sensor lacking of sensitivity.

Another reason is that the electric field hazards warning device according to U.S. Pat. No. 6,727,859 B1 comprises a mono-directional antenna system only. Thus, it is sensitive in a single direction. This makes it unsuitable for use as a sensor, unless the direction of the field to be measured is known precisely, which is barely the case.

### SUMMARY OF THE INVENTION

The present invention aims at providing an affordable EM field strength sensor with high sensitivity whatever the direction of the field, by combining an antenna with a cascade of amplifier cells. At its most general, the invention proposes an apparatus for measuring the strength of an electromagnetic field. The apparatus comprises a plurality of antennas arranged such that the field is received from all directions, each antenna supplying an RF signal as output. The apparatus also comprises a plurality of transforming modules, each of said modules being fed with the RF signal supplied by one of the antennas, each of said modules transforming the input impedance, so as to supply another RF signal as output. The apparatus also comprises a plurality of converting modules, each of said modules being fed with the RF signal supplied by one of the transforming modules, each of said modules converting the RF signal it receives as input into a DC current it supplies as output, said DC current varying substantially as a logarithmic function of the said RF signal.

Advantageously, the apparatus can further comprise a plurality of RMS modules for measuring the root mean square of the RF signal power, each converting module being put in parallel with a RMS module

In a preferred embodiment, each converting module may comprise a cascade of amplifiers, whose outputs may be summed together so as to generate a piecewise-linear approximation to the logarithmic function. For example, each converting module may comprise a RSSI circuit.

Advantageously, each transforming module may include a field effect transistor.

Advantageously, the apparatus may comprise a plurality of reading modules, each of said modules being fed with the DC current supplied by one of the converting modules.

Advantageously, each transforming module may convert the RF signal it receives as input, such that the apparatus may give a measure relative to a curve representing the protection levels for exposure to time-varying electromagnetic fields. The curve may be an inverted ICNIRP curve as published by the International Commission on Non-ionizing Radiation Protection.

Advantageously, the apparatus may comprise an analog-to-digital converter fed with the DC currents supplied by the plurality of converting modules, the said converter supplying a digital signal to a logging module. For example, the logging module may include a memory or a network interface.

Advantageously, the apparatus may comprise three antennas arranged orthogonally. For example, the antennas may include monopoles antennas or patch antennas or bowtie antennas.

In addition of being low-cost, an advantage provided by a sensor according to the present invention in any of its aspects is that it is wide frequency band and wide power range. Further advantages provided by a sensor according to the present invention in any of its aspects is that it enables easy measuring of fast changing fields in the three orthogonal directions (x, y and z). This is particularly convenient for measurement of EM fields in test environments. Yet another advantage provided by a sensor according to the present invention in any of its aspects is that it is small-sized and features a DC output (Direct Current). So, the sensor can be nested within an enclosure, the interferences due to the cable coming out from said enclosure being easily filtered. This is particularly convenient for evaluating the shielding effectiveness of the enclosure.

### BRIEF DESCRIPTION OF THE DRAWINGS

Non-limiting examples of the invention are described below with reference to the accompanying drawings in which:

FIG. 1 schematically illustrates cascaded amplifier stages giving a large dynamic range logarithmic function;

FIG. 2 schematically illustrates an exemplary embodiment of a field strength sensor with a high-impedance field effect transistor amplifier according to the invention;

FIG. 3 schematically illustrates another exemplary embodiment of a biological effect sensor according to the invention;

FIG. 4 schematically illustrates the reference levels for exposure to time varying electric fields published by ICNIRP.

In the figures, like reference signs are assigned to like items.

### DETAILED DESCRIPTION OF PREFERRED EMBODIMENTS

The cascading concept has been applied in RSSI circuits of mobile radios, where the transmitted power is controlled to the level that is needed so as to save battery lifetime. As already mentioned before, these RSSI circuits may seem unsuitable for use in a field strength sensor, because they have a too high noise level for extreme low amplitude field strength. However, the applicant had the opportunity to measure that amplitude fields are medium in case of measuring rapid changing fields or measuring transfer functions. Thus, unexpectedly, the use of RSSI circuits in a field strength sensor may be adapted to these cases.

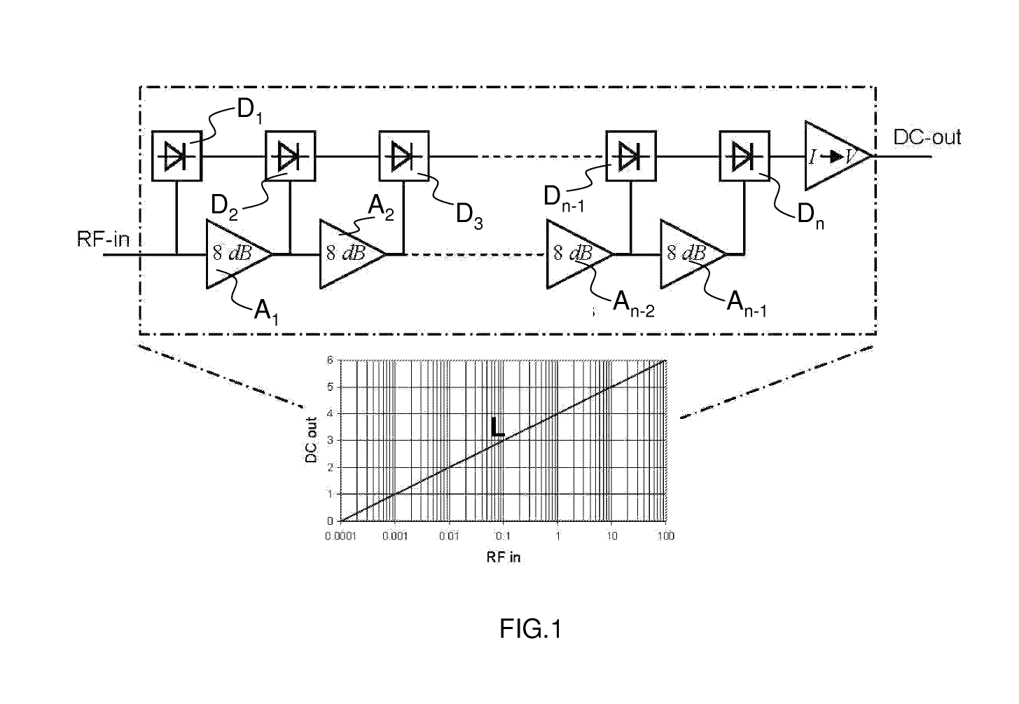

The FIG. 1 illustrates an exemplary series of n detectors referenced D1 to Dn. They are in connection with a cascade of n−1 wide-band amplifier cells referenced A1 to An-1, all the cells having a fixed gain, 8 decibels for example. The series of detectors are used to convert an RF-in signal to baseband. The outputs of the cells are summed together to generate a piecewise-linear approximation to a logarithmic function DC-out=L(RF-in) with a large dynamic range. The output is a DC voltage, whose amplitude is a measure of the RF-in voltage amplitude as illustrated by FIG. 1.

Several integrated circuits of this logarithmic detector are available on the market at a relatively low cost due to their widespread use in mobile phones. Frequency ranges of some hundreds of kilohertz (kHz) up to several gigahertz (GHz) are already available. The dynamic range is in theory unlimited, but due to crosstalk it will decrease at high frequencies, e.g. above 3 GHz, but we estimate that 90 decibels (dB) can be reasonably achieved. Recently, a comparable cascaded detector integrated circuit became available for measuring the root-mean, a measure for energy density, such a detector being hereinafter referred to as a RMS module.

According to an advantageous specificity of the current invention, such a RMS module can be applied in parallel to the peak logarithmic detector, so that both peak and RMS quantities can be measured (Root Mean Square).

Using a logarithmic amplifier for the peak detection and a similar, but electronically different, logarhithmic amplifier for RMS detection, these detections being realized simultaneously in all directions, allows measuring peak, RMS, crest factor.

An apparatus according to the current invention may further comprise means for averaging the DC output of the peak detector. By averaging the DC output of the peak detector, the average level of the RF signal is measured as well. The response time of these detector circuits is extremely short and a rapid changing field with changes in the order of 100 picoseconds shall be detected. Thus, the peak levels of modern digital signals can be measured easily.

Thus an apparatus according to the current invention can be operational over wide-frequency ranges, and thus also capable to measure pulsed signals, such as those used in Ultra Wide Band or High Power Microwave applications, and also capable of performing electromagnetic interference (EMI) measurements.

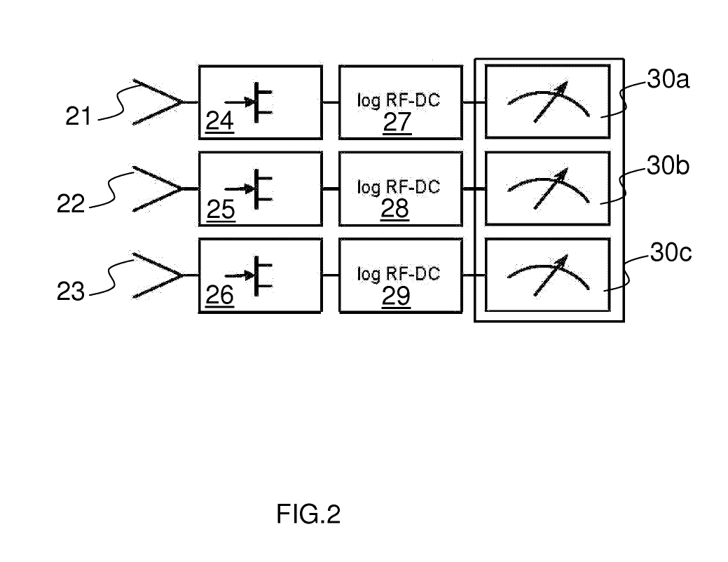

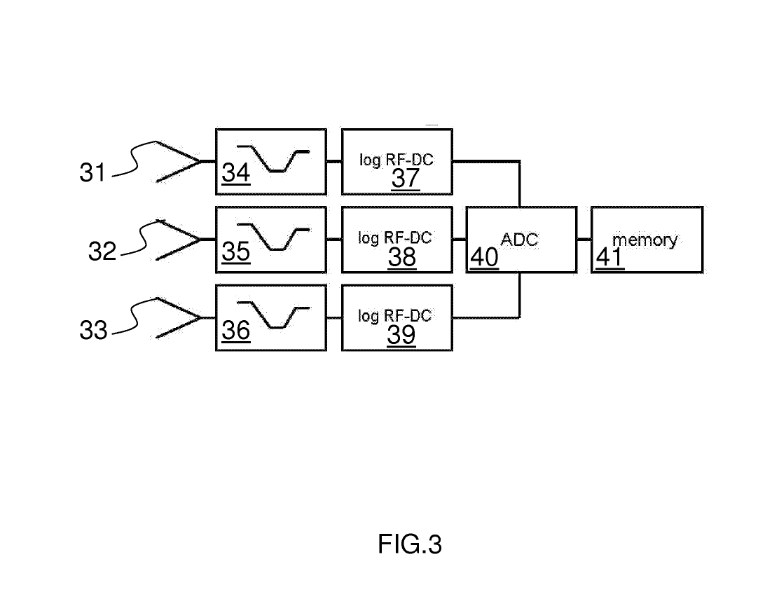

The antenna should be wide-band. A basic dipole is wideband, but has very high output impedance. This characteristic can be used advantageously in two different embodiments of the present invention. In a first embodiment illustrated by FIG. 2, a very wide band and still a large dynamic range field strength sensor comprises a high-input impedance Field Effect Transistor (FET), the FET being used as an impedance transformer. In another embodiment illustrated by FIG. 3, a biological effect sensor uses the high output impedance for ICNIRP correction.

The FIG. 2 schematically illustrates an exemplary embodiment of a field strength sensor according to the invention. It is worth noting that the RSSI circuits available on the market, which have not been developed for use in a sensor, do not comprise an antenna. The sensor comprises a 3-directionnal antenna system including three antennas referenced 21, 22 and 23 arranged orthogonally with respect to an X axis, a Y axis and a Z axis respectively. Antennas 21, 22 and 23 are wide-band antennas. They may be either short monopoles or patches or even inverted bowties. The sensor may also comprises three FETs referenced 24, 25 and 26 connected to the outputs of the antennas 21, 22 and 23 respectively. The FETs 24, 25 and 26 are used as impedance transformers. The sensor also comprises three logarithmic detectors referenced 27, 28 and 29 connected to the outputs of the FETs 24, 25 and 26 respectively. The logarithmic detectors 27, 28 and 29 are capable of peak measurement. As described hereinbelow, the logarithmic detectors 27, 28, 29 can be put in parallel with logarithmic amplifiers allowing RMS detection, nota shown on the figure. Then both peak and RMS measurements can be realized simultaneously. The electronics of the peak and RMS detectors can advantageously be packaged in one single module. The sensor comprises also a plurality of analog readouts 30a, 30b and 30c connected to the outputs of the three logarithmic detectors 27, 28 and 29 respectively.

Logarithmic detectors 27, 28 and 29 are core elements, which are being used in many mobile communication systems. As a result of this widespread use, the cost of a complete sensor according to the invention, including the antennas 21, 22 and 23, can be very low. This makes it possible to perform EM field mapping measurements for all kind of applications.

Moreover, the output level is direct current and any RF interference coupled into the interference can be filtered out in a simple manner, which makes these sensors a very low cost solution for field strength measurements.

Thus, the present invention may be implemented as a professional 3-directional electric and/or magnetic field sensor for measuring fast changing fields in a test environment. The present invention may also be implemented as a small 3-directional sensor for measuring transfer function and evaluating shielding effectiveness or coupling of fields through windows or doors or feedthrough panels. The present invention may also be implemented as a small low-cost 3-directional sensor for measuring field distribution inside a cavity.

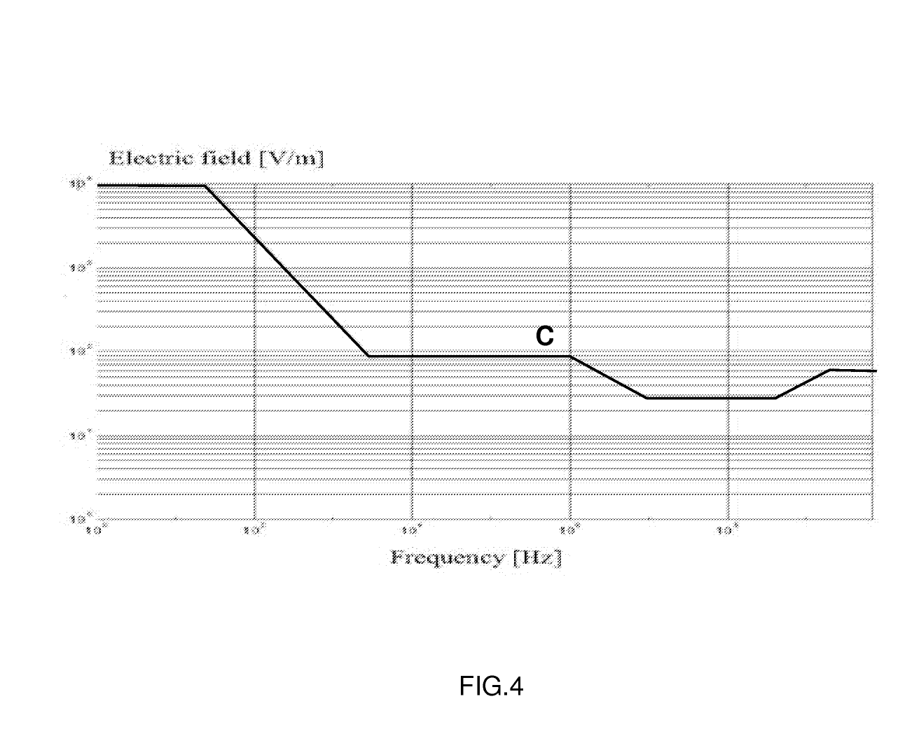

The FIG. 3 schematically illustrates an exemplary embodiment of a biological effect sensor according to the invention. The sensor comprises a 3-directionnal antenna system including three antennas referenced 31, 32 and 33 arranged orthogonally with respect to an X axis, a Y axis and a Z axis respectively. Antennas 31, 32 and 33 are wide-band antennas. They may be either short monopoles or patches or even inverted bowties. The sensor may also comprise three ICNIRP converters referenced 34, 35 and 36 connected to the outputs of the antennas 31, 32 and 33 respectively. The ICNIRP converters 34, 35 and 36 form a passive bio-compensation network to compensate for an ICNIRP curve C illustrated by FIG. 4. The protection levels for exposure to time-varying electric, magnetic and electromagnetic fields are published by ICNIRP, as illustrated by FIG. 4. The curve C shown in FIG. 4 may be embedded in the passive bio-compensation network after said curve has been inverted, such that the output of the sensor gives a value relative to the curve C. Indeed, the ICNIRP levels are frequency dependant but the sensor does not know which frequency it is measuring: the sensor converts any RF level to a corresponding DC level. For instance, the ICNIRP level may be 100 volts per metre (V/m) in some frequency range, while it may be 27 V/m in another range. The present invention proposes that the bio-compensation network corrects the RF level as a function of the frequency. The effect is that when an RF signal of 50 V/m is measured in the part of ICNIRP where the limit is 100 V/m, then the readout is 50% (actually −6 dB). If an RF signal of 50 V/m is measured in the range where the ICNIRP curve is 27 V/m, then the readout is +5.4 dB (i.e. 20 log (50/27)).

The sensor also comprises three logarithmic detectors referenced 37, 38 and 39 connected to the outputs of the ICNIRP converters 34, 35 and 36 respectively. The logarithmic detectors 37, 38 and 39 are capable of peak measurement. As described hereinbelow, the logarithmic detectors 37, 38, 39 can be put in parallel with logarithmic amplifiers allowing RMS detection, nota shown on the figure. Then both peak and RMS measurements can be realized simultaneously. The electronics of the peak and RMS detectors can advantageously be packaged in one single module. The sensor comprises also an analog-to-digital converter referenced 40 (ADC) connected to the outputs of the three logarithmic detectors referenced 37, 38 and 39. The sensor may also comprise a multichannel logging memory referenced 41, allowing the DC level to be stored in a logging memory. In another embodiment, the multichannel logging memory 41 may be replaced by a network interface to transmit data to a computer, allowing the DC level to be transmitted via a network to a central computer.

In addition of providing a broadband, fast, tri-axial, high-dynamic range and low-cost EM field strength sensor, a further advantage of the present invention is that it can also be used as a biological effect sensor. Embodied as a body-worn device the size of a USB stick, the resulting biological effect sensor may then be provided with a correction curve integrated within the antenna system, so as to measure levels with respect to the international limits. When provided with a digital logging memory for storing data or when connected to a network, the resulting biological effect sensor can make a readout periodically, so as to enable the creation of an EM exposure map of the environment. Distributed over a network, for instance inside a hospital or around primary schools, such biological effect sensor may also monitor the field strength.

1. An apparatus for measuring the strength of an electromagnetic field, the apparatus comprising:
a plurality of antennas arranged such that the field is received from all directions, each antenna supplying an RF signal as output;
a plurality of transforming modules each of said modules being fed with the RF signal supplied by one of the antennas, each of said modules transforming the input impedance, so as to supply another RF signal as output;
a plurality of converting modules, each of said modules being fed with the RF signal supplied by one of the transforming modules, each of said modules converting the RF signal it receives as input into a DC current it supplies as output, said DC current varying substantially as a logarithmic function of the said RF signal.

2. An apparatus according to claim 1, further comprising a plurality of RMS modules for measuring the root mean square of the RF signal power, each converting module being put in parallel with a RMS module.

3. An apparatus according to claim 1, wherein each converting module comprises a cascade of amplifiers, whose outputs are summed together so as to generate a piecewise-linear approximation to the logarithmic function.

4. An apparatus according to claim 1, wherein each converting module comprises a RSSI circuit.

5. An apparatus according to claim 1, wherein each transforming module includes a field effect transistor.

6. An apparatus according to claim 5, comprising a plurality of reading modules, each of said modules being fed with the DC current supplied by one of the converting modules.

7. An apparatus according to claim 1, wherein each transforming module converts the RF signal it receives as input, such that the apparatus gives a measure relative to a curve representing the protection levels for exposure to time-varying electromagnetic fields.

8. An apparatus according to claim 7, wherein the curve is an inverted ICNIRP curve.

9. An apparatus according to claim 7, comprising an analog-to-digital converter fed with the DC currents supplied by the plurality of converting modules, the said converter supplying a digital signal to a logging module.

10. An apparatus according to claim 9, wherein the logging module includes a memory or a network interface.

11. An apparatus according to claim 1, comprising three antennas arranged orthogonally.

12. An apparatus according to claim 1, wherein the antennas include monopoles antennas or patch antennas or bowtie antennas.
